(19) United States
(12) Patent Application Publication
(10) Pub. No.: US 2016/0322375 A1
(43) Pub. Date: Nov. 3, 2016

(54) NON-VOLATILE MEMORY DEVICE AND METHOD FOR MANUFACTURING SAME

(71) Applicant: Kabushiki Kaisha Toshiba, Minato-ku (JP)

(72) Inventors: Ryota SUZUKI, Yokkaichi (JP); Tatsuya Kato, Yokkaichi (JP)

(73) Assignee: Kabushiki Kaisha Toshiba, Minato-ku (JP)

(21) Appl. No.: 14/838,518

(22) Filed: Aug. 28, 2015

Related U.S. Application Data
(60) Provisional application No. 62/154,938, filed on Apr. 30, 2015.

(51) Int. Cl. H01L 27/115; H01L 27/02

(52) U.S. Cl. CPC H01L 27/11573; H01L 27/0207; H01L 27/11524; H01L 27/11526; H01L 27/1157

(57) ABSTRACT

A non-volatile memory device includes a substrate having a first area and a second area around the first area, memory cells in the first area. Each memory cell includes a semiconductor body, an electrode layer and a stacked body including a charge storage layer between the semiconductor layer and the electrode layer. The device includes an STI provided between the memory cells and an insulating film provided between the stacked body and the electrode layer. The STI has a top surface at the same height level as a top surface of the stacked body. The device further includes a capacitor element in the second area, which includes a first conductive layer, a dielectric film on the first conductive layer and a second conductive layer on the dielectric film. The dielectric film includes at least one layer that contains the same material as a material included in the insulating film.

### CROSS-REFERENCE TO RELATED APPLICATIONS

This application is based upon and claims the benefit of priority from U.S. Provisional Patent Application 62/154,938 filed on Apr. 30, 2015; the entire contents of which are incorporated herein by reference.

### FIELD

Embodiments are generally related to a non-volatile memory device and a method for manufacturing the same.

### BACKGROUND

A non-volatile memory device comprises a memory cell array including multiple memory cells and a peripheral circuit for driving the memory cells. For example, the NAND-type flash memory comprises a memory cell that includes a semiconductor channel, a word line and a charge storage layer disposed between the semiconductor channel and the word line. The peripheral circuit is connected to the memory cell via the word line and a bit line connected to the semiconductor layer, and performs writing data, reading data and erasing data in the memory cell through the word line and the bit line. The peripheral circuit includes, for example, a switching element, a resistor element, a capacitor element, etc., and these circuit elements are preferably formed using a material common to a memory cell element, such as the charge storage layer, the word line, an insulating film therebetween, or the like. When the common material may be used for a part of each circuit element and one of the memory cell elements, however, a suitable thickness of the part is sometime different from a thickness of the memory cell element.

### BRIEF DESCRIPTION OF THE DRAWINGS

FIGS. 1A and 1B are schematic plan views showing a non-volatile memory device according to a first embodiment;

FIG. 2 is a schematic cross-sectional view showing the non-volatile memory device according to the first embodiment;

FIGS. 3A to 3D are schematic cross-sectional views showing peripheral circuit elements of the non-volatile memory device according to the first embodiment;

FIGS. 4A to 9B are schematic cross-sectional views showing a manufacturing process of the non-volatile memory device according to the first embodiment;

FIGS. 10A to 10E are schematic cross-sectional views showing a manufacturing process of a non-volatile memory device according to a second embodiment;

FIG. 11 is a schematic cross-sectional view showing the non-volatile memory device according to the second embodiment; and

FIG. 12 is a schematic cross-sectional view showing a peripheral circuit element according to a comparative example.

### DETAILED DESCRIPTION

According to one embodiment, a non-volatile memory device comprises a substrate including a first area and a second area around the first area, first and second memory cells in the first area. The first memory cell includes a first semiconductor body extending in a first direction, an electrode layer extending over the first semiconductor body in a second direction intersecting the first direction, and a first stacked body provided at an intersection of the first semiconductor body and the electrode layer. The first stacked body includes a first insulating film on the first semiconductor body, a first charge storage layer on the first insulating film and a second insulating film between the first charge storage layer and the electrode layer. The second memory cell shares the electrode layer with the first memory cell. The second memory cell includes a second semiconductor body and a second stacked body. The second semiconductor body extends in the first direction, and the electrode layer extends over the second semiconductor body in the second direction. The second stacked body is provided at an intersection of the second semiconductor body and the electrode layer, and includes a third insulating film on the second semiconductor body, a second charge storage layer on the third insulating film and a fourth insulating film between the second charge storage layer and the electrode layer. The device includes a fifth insulating film provided between the first stacked body and the second stacked body and a sixth insulating film provided between the electrode layer and each of the second insulating film, the fourth insulating film and the fifth insulating film. The sixth insulating film is one of a single-layer film and a stacked film. A first interface between the second insulating film and the sixth insulating film and a second interface between the fourth insulating film and the sixth insulating film are provided at the substantially same height level as a height level of a third interface between the fifth insulating film and the sixth insulating film. The device further includes a capacitor element in the second area. The capacitor element includes a third semiconductor body, a first conductive layer provided on the third semiconductor body, a dielectric film provided on the first conductive layer and a second conductive layer provided on the dielectric film. The dielectric film includes at least one layer that contains the same material as a material included in the sixth insulating film.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

### First Embodiment

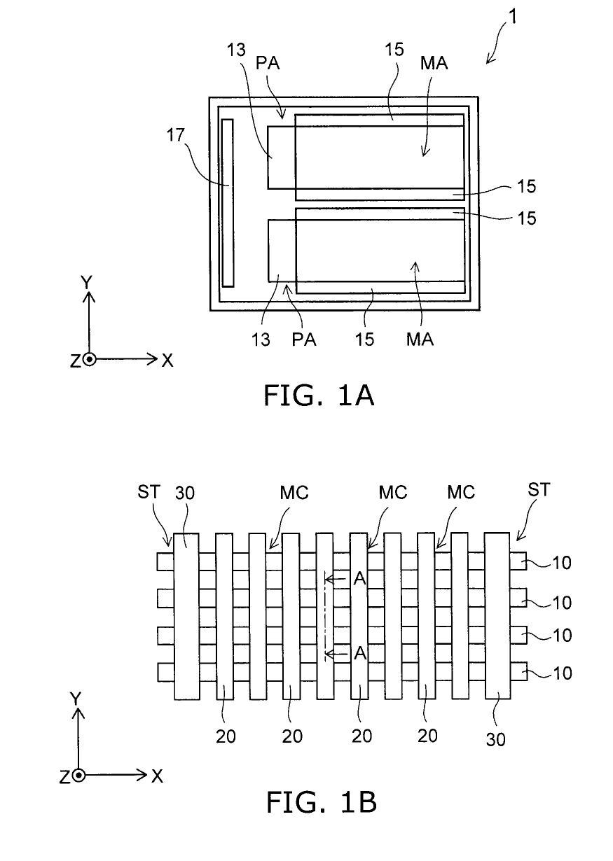

FIGS. 1A and 1B are schematic plan views showing a non-volatile memory device 1 according to a first embodiment. FIG. 1A is a schematic view showing a chip surface of the non-volatile memory device 1. FIG. 1B is a schematic view showing the arrangement of memory cells in the non-volatile memory device 1.

The non-volatile memory device 1 is, for example, an NAND-type flash memory. As shown in FIG. 1A, the non-volatile memory device 1 has a first area (hereinafter referred to as “memory area MA”) and a second area (hereinafter referred to as “peripheral area PA”), both of which are provided on a semiconductor substrate, for example. The memory area MA includes multiple memory cells MC. The peripheral area PA is provided around the memory area MA. The peripheral area PA includes, for example, peripheral circuits such as a sense amplifier 13 and a row decoder 15. Further, in the peripheral area PA, a connection area 17 is provided. The connection area 17 includes a pad for electrically connecting the peripheral circuits to an external terminal (not shown).

As shown in FIG. 1B, multiple semiconductor bodies 10 are provided in the memory area MA. Each of the semiconductor bodies 10 extends in a first direction (hereinafter referred to as “X-direction”). The semiconductor bodies 10 are provided side by side in a second direction (hereinafter referred to as “Y-direction”) crossing the first direction.

Multiple electrode layers 20 are further provided in the memory area MA. Each of the electrode layers 20 is, for example, a word line extending in the Y-direction on the multiple semiconductor bodies 10. The multiple memory cells MC are provided at the intersections of the semiconductor bodies 10 and the electrode layers 20.

The electrode layers 20 are provided side by side in the X-direction as shown in FIG. 1B. Selection gates 30 are provided respectively on both sides of the multiple electrode layers 20. The multiple electrode layers 20 are provided between one of the selection gates 30 and the other of the selection gates 30 in the X-direction. The selection gates 30 extend in the Y-direction over the multiple semiconductor bodies 10. Selection transistors ST is provided at the intersections of the semiconductor bodies 10 and the selection gates 30. That is, multiple memory cells MC are provided side by side in the X-direction on each semiconductor body 10. Then, a pair of selection transistors ST is disposed respectively on both sides of the multiple memory cells MC. The multiple memory cells are provided between the pair of the selection transistors ST.

The semiconductor body 10 is electrically connected to the sense amplifier 13 via a bit line (not shown). The electrode layer 20 and the selection gate 30 are electrically connected to, for example, the row decoder 15. The row decoder 15 controls the electrical conduction between the semiconductor body 10 and each of the bit line and a source line by turning the selection transistor ST on or off.

The row decoder 15, for example, electrically connects the semiconductor body 10 to the sense amplifier 13 by turning the selection transistor ST on, and selectively applies voltages to the memory cells MC through the electrode layer 20. Thereby, data is written in a memory cell selected therefor. The sense amplifier 13 can read out data stored in the memory cell MC.

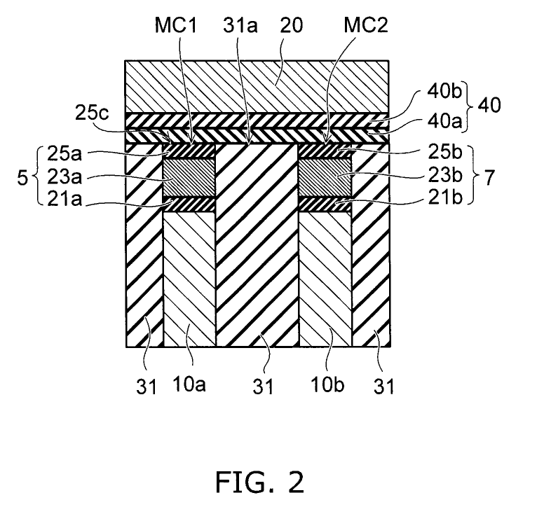

Next, the structure of the memory cell MC of the non-volatile memory device 1 will be described with reference to FIG. 2. FIG. 2 is a schematic view showing the cross section taken along the line A-A in FIG. 1B.

A first memory cell MC1 includes a first semiconductor body 10a, an electrode layer 20, and a first stacked body 5 as shown in FIG. 2. A second memory cell MC2 includes a second semiconductor body 10b, an electrode layer 20, and a second stacked body 7. The first stacked body 5 includes a first insulating film (hereinafter referred to as “insulating film 21a”), a first charge storage layer (hereinafter referred to as “charge storage layer 23a”), and a second insulating film (hereinafter referred to as “insulating film 25a”). The second stacked body 7 includes a third insulating film (hereinafter referred to as “insulating film 21b”), a second charge storage layer (hereinafter referred to as “charge storage layer 23b”), and a fourth insulating film (hereinafter referred to as “insulating film 25b”). The insulating film 21 acts as a so-called tunnel insulating film between the semiconductor body 10 and the charge storage layer 23.

Note that there are the cases in the specification, where the insulating films 21 are distinguished from each other as the insulating film 21a and the insulating film 21b and where the insulating films 21a and 21b are collectively referred to as the insulating film 21. The same shall apply to the other constituent components.

A fifth insulating film (hereinafter referred to as “STI 31”) is provided between the first stacked body 5 and the second stacked body 7. A shallow trench isolation (STI 31) is provided to isolate the first semiconductor body 10a from the second semiconductor body 10b, and to electrically insulate the first memory cell MC1 from the second memory cell MC2.

Further, the second stacked body 7, and the STI 31, a sixth insulating film (hereinafter referred to as “insulating film 40”) is provided between the electrode layer 20 and each of the first stacked body 5 as shown in FIG. 2. The insulating film 40 is extended in the Y-direction along the electrode layer 20.

The insulating film 40 is, for example, a stacked film including a first film 40a and a second film 40b. The first film 40a is provided on the insulating film 25 and the STI 31. The first film 40a is, for example, an insulating film that contains silicon. The second film 40b is provided on the first film 40a and is in contact with the electrode layer 20. The second film 40b is, for example, a metal oxide film such as a hafnium oxide film.

The insulating film 40 is in contact with the STI 31. Further, the insulating film 40 is in contact with the fourth insulating film (insulating film 25) in the first memory cell MC1 and the second memory cell MC2. An interface 25c between the insulating film 25 and the insulating film 40 is positioned at the same level as an interface 31a between the STI 31 and the insulating film 40. In other words, the upper surface of the STI 31 and the upper surface of the insulating film 25 are in the same plane, and the insulating film 40 is extended in the Y-direction on the upper surface of the STI 31 and the upper surface of the insulating film 25. Here, the term “same” is not limited to the case where the levels (or heights) are identical in a strict sense. The levels (or heights) may be substantially the same, wherein a difference due to inaccuracy in a manufacturing process is allowed.

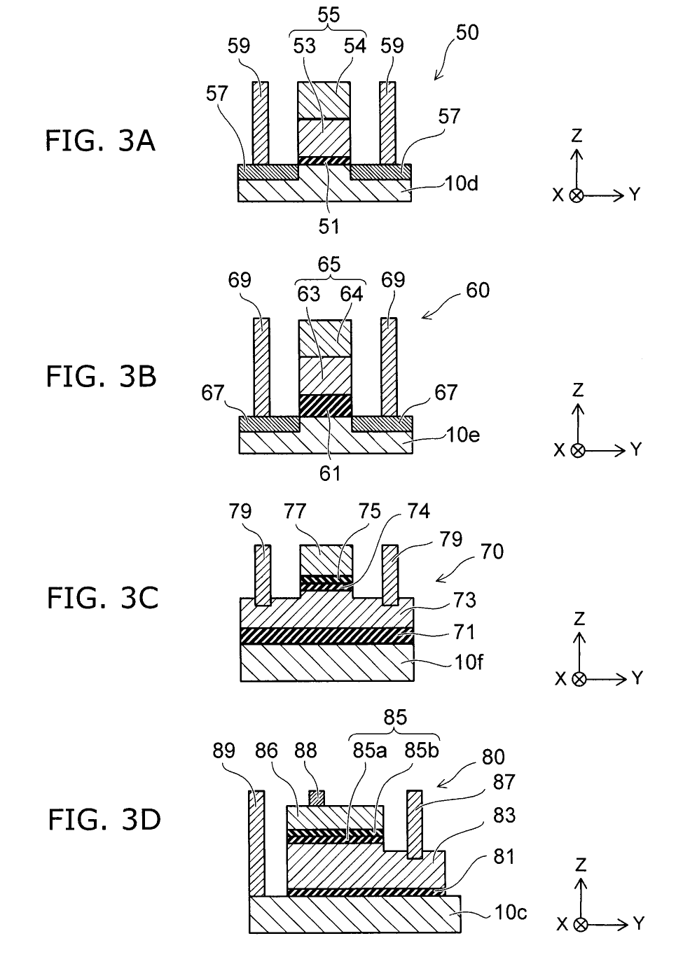

Next, with reference to FIGS. 3A to 3D, circuit elements included in a peripheral circuit of the non-volatile memory device 1 will be described. In the peripheral area PA, for example, a switching element, a resistor element, a capacitor element, and the like are disposed.

FIG. 3A is a cross-sectional view of a switching element 50. The switching element 50 includes a fourth semiconductor body 10d, an eighth insulating film (hereinafter referred to as “gate insulating film 51”), and a gate electrode 55. The gate insulating film 51 is provided on the fourth semiconductor body 10d. The gate electrode 55 is provided on the gate insulating film 51, and includes, for example, a third conductive layer (hereinafter referred to as “conductive layer 53”) and a fourth conductive layer (hereinafter referred to as “metal layer 54”). The fourth semiconductor body 10d includes source/drain areas 57 provided on both sides of the gate insulating film 51. Then, contact members 59 in contact with the source/drain areas 57 are provided.

The gate insulating film 51 is composed of, for example, the same material as that of the insulating film 21 of the memory cell MC. Further, the conductive layer 53 is composed of, for example, the same material as that of the charge storage layer 23. The metal layer 54 is composed of the same material as that of the electrode layer 20.

FIG. 3B is a cross-sectional view of a switching element 60. The switching element 60 includes a semiconductor body 10e, a gate insulating film 61, and a gate electrode 65. The gate insulating film 61 is provided on the semiconductor body 10e. The gate electrode 65 is provided on the gate insulating film 61, and includes, for example, a conductive layer 63 and a metal layer 64. The semiconductor body 10e includes source/drain areas 67 provided on both sides of the gate insulating film 61. Then, contact members 69 are provided, which are connected to the source/drain areas 67 respectively.

The film thickness of the gate insulating film 61 is larger than that of the gate insulating film 51. That is, the gate breakdown voltage of the switching element 60 is higher than that of the switching element 50. Further, the conductive layer 63 is composed of, for example, the same material as that of the charge storage layer 23. The metal layer 64 is composed of the same material as that of the electrode layer 20.

FIG. 3C is a cross-sectional view of a resistor element 70. The resistor element 70 includes a conductive layer 73 and contact members 79 in contact with the conductive layer 73. The conductive layer 73 is provided on a semiconductor body 10f via an insulating film 71. Further, the resistor element 70 includes insulating films 74 and 75 and a metal layer 77 selectively provided on the conductive layer 73. That is, the resistor element 70 is formed by sequentially stacking the conductive layer 73, the insulating films 74 and 75, and the metal layer 77 on the semiconductor body 10f, and thereafter selectively removing the insulating films 74 and 75, and the metal layer 77.

The conductive layer 73 is composed of, for example, the same material as that of the charge storage layer 23. The insulating film 74 is composed of, for example, the same material as that of the first film 40a of the insulating film 40. The insulating film 75 is composed of, for example, the same material as that of the second film 40b. The metal layer 77 is composed of the same material as that of the electrode layer 20.

FIG. 3D is a cross-sectional view of a capacitor element 80. The capacitor element 80 is provided on a third semiconductor body 10c via an insulating film 81. The capacitor element 80 includes a conductive layer 83 (first conductive layer), a dielectric film 85, and a metal layer 86 (second conductive layer). The dielectric film 85 has a structure in which at least one layer is composed of the same material as a material of the insulating film 40. For example, the dielectric film 85 includes a first film 85a and a second film 85b.

The capacitor element 80 is formed by sequentially stacking the conductive layer 83, the dielectric film 85, and the metal layer 86, and thereafter selectively removing the metal layer 86 and the dielectric film 85. Then, a first contact member 87 is provided so as to be connected to the conductive layer 83, and a second contact member 88 is provided so as to be connected to the metal layer 86. Further, a contact member 89 is provided so as to be in contact with the third semiconductor body 10c.

The conductive layer 83 is composed of, for example, the same material as a material of the charge storage layer 23. The first film 85a of the dielectric film 85 is composed of the same material as a material of the first film 40a of the insulating film 40. The second film 85b is composed of the same material as a material of the second film 40b of the insulating film 40. The metal layer 86 is composed of the same material as a material of the electrode layer 20.

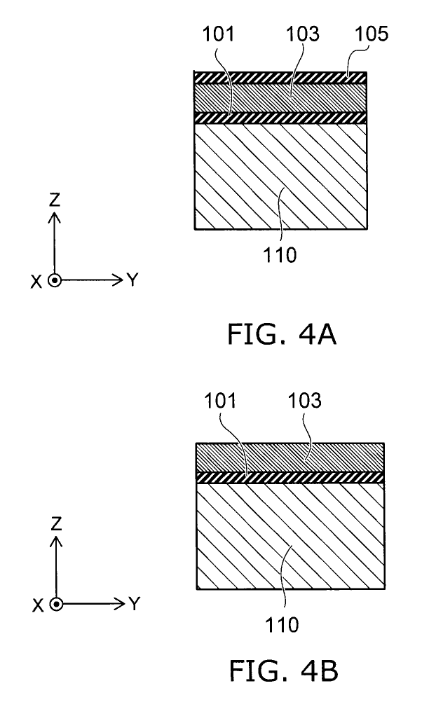

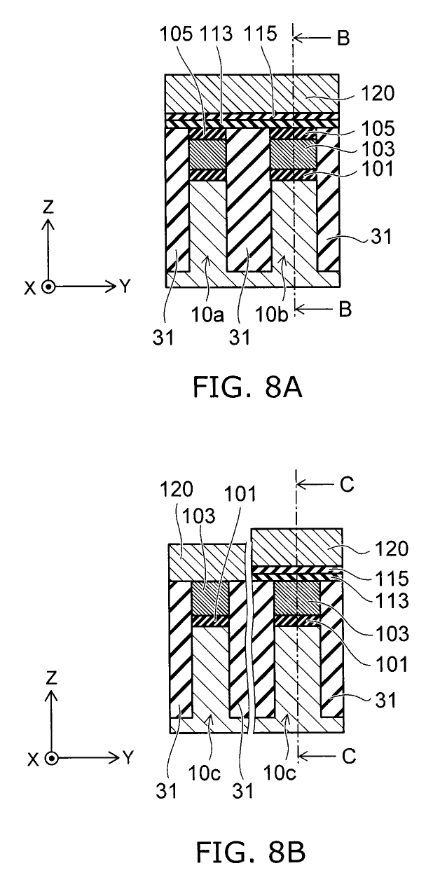

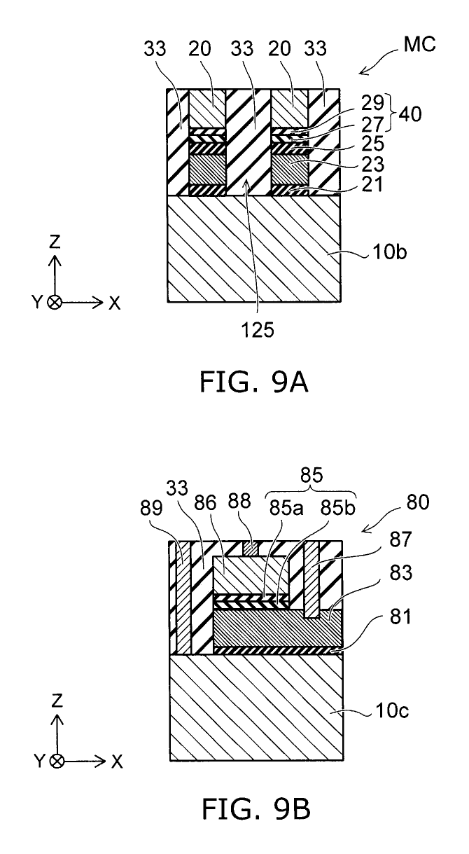

Next, with reference to FIGS. 4A to 9B, a method for manufacturing the non-volatile memory device 1 according to the first embodiment will be described. FIGS. 4A to 9B are schematic cross-sectional views sequentially showing the process for manufacturing the non-volatile memory device 1. FIGS. 4A, 5A, 6A, 7A, 8A, and 9A are cross sections of the memory area MA, and FIGS. 4B, 5B, 6B, 7B, 8B, and 9B are cross sections of the peripheral area PA. FIGS. 4A to 8B show cross sections parallel to the Y-Z plane, and FIG. 9A and FIG. 9B show a cross section taken along the line B-B of FIG. 8A and a cross section taken along the line C-C of FIG. 8B, respectively.

As shown in FIG. 4A, an insulating film 101, a conductive layer 103, and an insulating film 105 are sequentially stacked on a semiconductor substrate 110. The semiconductor substrate 110 is, for example, a silicon substrate. The insulating film 101 is, for example, a silicon oxide film. The conductive layer 103 is, for example, a polysilicon layer. The insulating film 105 is, for example, a metal oxide film such as a hafnium oxide film.

As shown in FIG. 4B, a portion of the insulating film 105 deposited on the peripheral area PA is selectively removed.

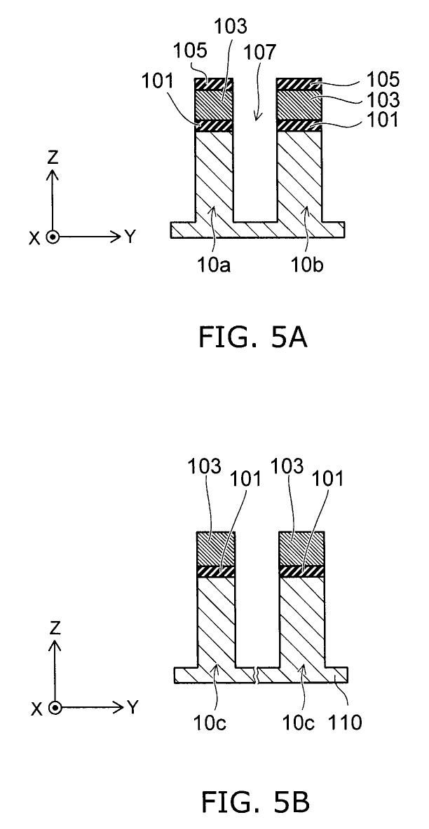

As shown in FIGS. 5A and 5B, a trench 107 is formed to reach the semiconductor substrate 110 from the upper surface of the insulating film 105. The trench 107 is extended in the X-direction. Thus, a first semiconductor body 10a, a second semiconductor body 10b, and a third semiconductor body 10c are formed on an upper side of the semiconductor substrate 110.

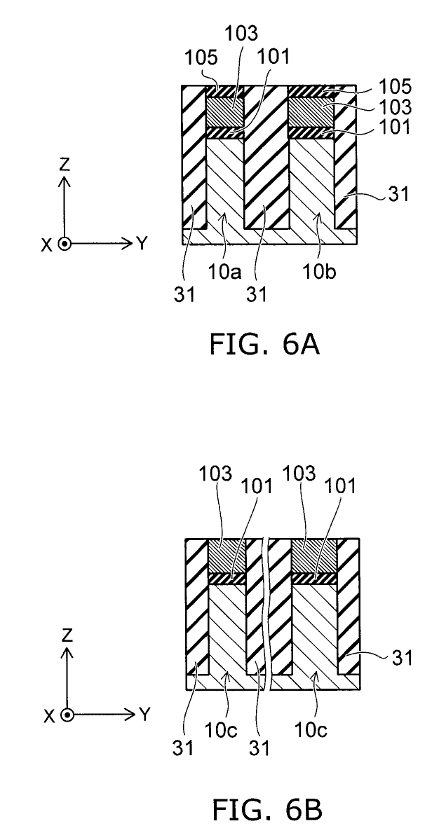

As shown in FIGS. 6A and 6B, a STI 31 is formed inside the trench 107. The STI 31 is, for example, a silicon oxide film. As shown in FIG. 6A, the STI 31 is formed such that the upper surface of the STI 31 is positioned at the same level as the upper surface of the insulating film 105. For example, a silicon oxide film is formed such that the silicon oxide film is buried inside the trench 107 and covers the insulating film 105. Subsequently, the silicon oxide film is etched back to expose the upper surface of the insulating film 105. As shown in FIG. 6B, the conductive layer 103 is exposed in the peripheral area PA.

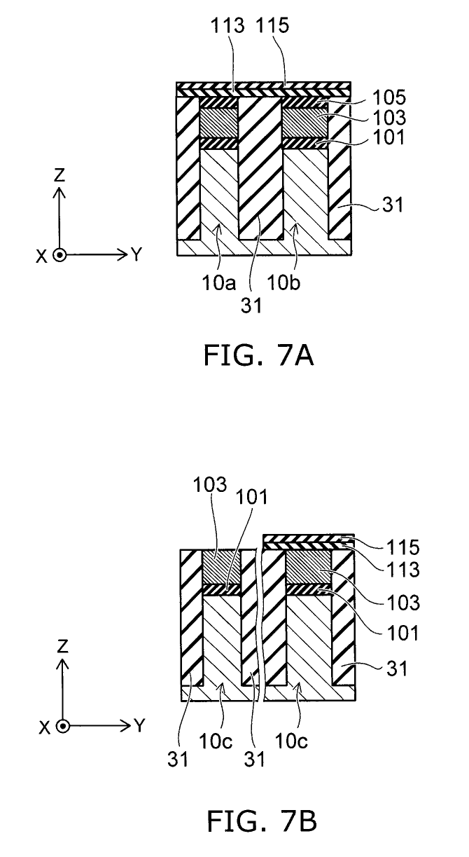

As shown in FIGS. 7A and 7B, an insulating film 113 and an insulating film 115 are sequentially formed. The insulating film 113 contains, for example, silicon. The insulating film 115 is, for example, a metal oxide film such as a hafnium oxide film. As shown in FIG. 7A, the insulating film 113 covers the surface of the insulating film 105 and the surface of the STI 31. As shown in FIG. 7B, the insulating films 113 and 115 are selectively formed in the peripheral area PA. That is, the insulating films 113 and 115 are selectively removed in a part of the peripheral area PA where the switching elements 50 and 60 are provided.

As shown in FIGS. 8A and 8B, a metal layer 120 is formed on the insulating film 113. The metal layer 120 is, for example, a tungsten (W) film. The metal layer 120 may be, for example, a multilayer film in which a titanium nitride (TiN) film and a tungsten film are sequentially stacked. The titanium nitride film acts as barrier metal for example. As shown in FIG. 8B, in the peripheral area PA, the metal layer 120 is directly formed on the conductive layer 103 in the part of the peripheral area PA where the switching elements 50 and 60 are provided.

As shown in FIG. 9A, a trench 125 which extends in the Y-direction is formed on the semiconductor body 10 to divide the stacked body, and an insulating film 33 is buried inside the trench 125. The trench 125 is formed, for example, with a depth so as to reach the semiconductor body 10 from the upper surface of the metal layer 120. Alternatively, the trench 125 may be formed with a depth so as to reach the insulating film 101 from the upper surface of the metal layer 120. That is, the insulating film 101 may not be divided by the trench 125. The insulating film 33 is, for example, a silicon oxide film.

Thus, multiple insulating films 21, multiple charge storage layers 23, multiple insulating films 25, multiple insulating films 40, and multiple electrode layers 20 are formed on the semiconductor body 10b. The insulating films 21 are made from the insulating film 101, which are mutually separated by the trenches 107 and 125. The charge storage layers 23 are made from the conductive layer 103, which are mutually separated by the trenches 107 and 125. The insulating films 25 are made from the insulating film 105, which are mutually separated by the trenches 107 and 125. The insulating films 40 are made from the insulating films 113 and 115, which are mutually separated by the trench 125 and extend in the Y-direction. The electrode layers 20 are made from the metal layer 120, which are mutually separated by the trench 125, and are extended in the Y-direction.

The switching elements 50 and 60, the resistor element 70, and the capacitor element 80 are formed in the peripheral area PA.

FIG. 9B is a cross-sectional view showing the capacitor element 80. For example, the conductive layer 83 of the capacitor element 80 is formed by selectively etching the conductive layer 103. The dielectric film 85 and the metal layer 86 are formed by selectively etching the insulating films 113 and 115 and the metal layer 120. The first film 85a of the dielectric film 85 is a portion of the insulating film 113, and the second film 85b is a portion of the insulating film 115.

The capacitor element 80 is, for example, covered with the insulating film 33 on the third semiconductor body 10c. Then, the contact member 87 is provided so as to reach the conductive layer 83 from the upper surface of the insulating film 33. The contact member 88 is provided so as to reach the metal layer 86 from the upper surface of the insulating film 33. The contact member 89 is provided to reach the third semiconductor body 10c from the upper surface of the insulating film 33.

It is preferable to provide a metal silicide between the conductive layer 83 and the contact member 89 for decreasing the contact resistance therebetween. The same shall also apply between the conductive layer 73 of the resistor element 70 and the contact member 79.

In the switching element 50 shown in FIG. 3A, the gate insulating film 51 is, for example, made from the insulating film 101. Further, the conductive layer 53 of the gate electrode 55 is made from the conductive layer 103, and the metal layer 54 of the gate electrode 55 is made from the metal layer 120.

In the switching element 60 shown in FIG. 3B, the conductive layer 63 of the gate electrode 65 is made from the conductive layer 103, and the metal layer 64 of the gate electrode 65 is made from the metal layer 120.

Further, in the resistor element 70 shown in FIG. 3C, the conductive layer 73 is made from the conductive layer 103. Further, the insulating film 74 is made from the insulating film 113, and the insulating film 75 is made from the insulating film 115. The metal layer 77 is made from the metal layer 120.

In this manner, the manufacturing process of the non-volatile memory device 1 may be simplified by forming the constituent components of the respective circuit elements provided in the peripheral area PA and the constituent components of the memory cell MC using the insulating film 101, the conductive layer 103, the insulating films 113 and 115, and the metal layer 120. The manufacturing cost thereof may be also reduced, and the manufacturing yield thereof may be improved.

In the embodiment, the insulating films 25 provided immediately above the charge storage layer 23 are mutually spaced apart in the X-direction and the Y-direction. On the other hand, the insulating film 40 provided on the insulating films 25 is formed so as to extend in the Y-direction along the electrode layer 20. Then, the insulating films 25 and the insulating film 40 include, for example, a metal oxide film having a higher dielectric constant than that of a silicon oxide film. According to such a structure, a leak current is decreased between the electrode layer 20 and the charge storage layer 23, and further, the coupling ratio is increased in the memory cell MC. Thereby, an applied voltage is reduced while writing data and erasing data in the memory cell MC. The reliability of the memory cell MC may be also improved. Here, the coupling ratio refers to, for example, a ratio of a capacitance between the semiconductor body 10 and the charge storage layer 23 to a capacitance between the electrode layer 20 and the charge storage layer 23.

On the other hand, the dielectric film 85 of the capacitor element 80 provided in the peripheral area PA is composed of the same material as the material of the insulating film 40, and the dielectric film 85 is formed, for example, to have the same film thickness as the thickness of the insulating film 40. For example, not providing the insulating film 25 between the electrode layer 20 and the charge storage layer 23 in the peripheral area PA makes the thickness of the dielectric film 85 smaller than a thickness of the dielectric film in the case where both of the insulating film 25 and the insulating film 40 are provided in the peripheral area PA. Thus, it may be possible to reduce the area of the capacitor element 80 without the reduction of capacitance thereof, and the peripheral circuit area may be decreased in the chip area.

### Second Embodiment

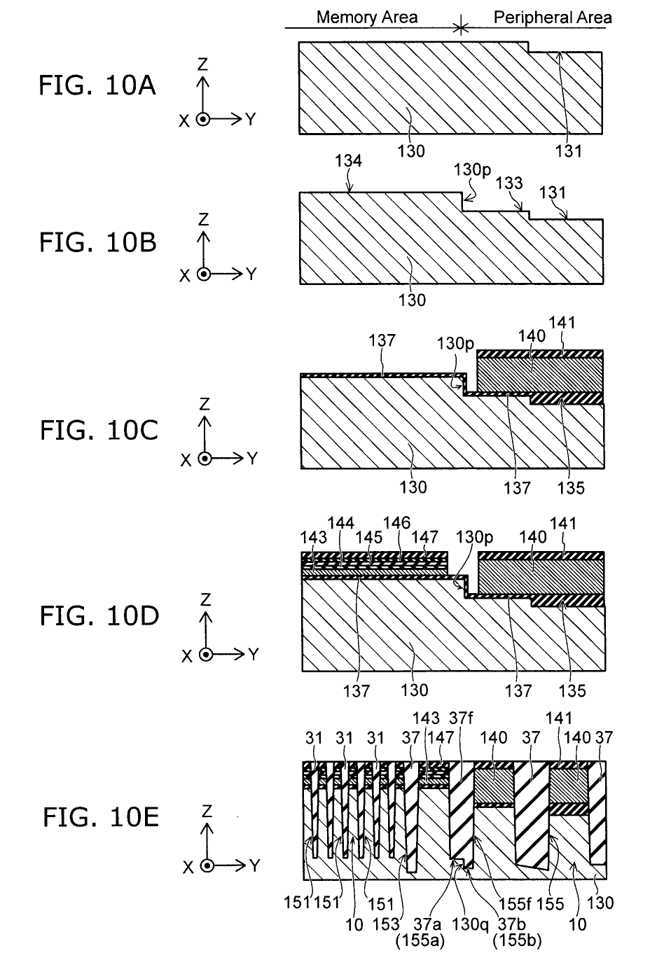

With reference to FIGS. 10A to 10E, a method for manufacturing a non-volatile memory device 1 according to a second embodiment will be described. FIGS. 10A to 10E are schematic cross-sectional views sequentially showing a process for manufacturing the non-volatile memory device 1.

As shown in FIG. 10A, a partial area 131 is selectively etched in a semiconductor substrate 130. A switching element 60 having a high breakdown voltage is formed in the area 131, for example.

As shown in FIG. 10B, the peripheral area PA is further removed, forming a step portion 130p. Thus, a surface 133 (second surface) of the peripheral area PA is provided at a lower level than a level of a surface 134 (first surface) in the memory area MA. The surface 133 includes a surface 131 (third surface), and the surface 131 is provided at a further lower level than the level of the surface 133.

As shown in FIG. 10C, an insulating film 137 is formed on the surface 134 of the memory area MA and the surface 133 of the peripheral area PA. The insulating film 137 is, for example, a silicon oxide film. Further, an insulating film 135 is formed on the area 131. The insulating film 135 is thicker than the insulating film 137. The insulating film 135 is, for example, a silicon oxide film.

Then, a conductive layer 140 is formed so as to cover the peripheral area PA. The conductive layer 140 is, for example, a polysilicon layer. The conductive layer 140 is formed to be thicker than a step height of the step portion 130p. Further, an insulating film 141 is formed on the conductive layer 140. The insulating film 141 is, for example, a silicon nitride film. The conductive layer 140 and the insulating film 141 are formed sequentially on the semiconductor substrate 130, for example, by CVD (Chemical Vapor Deposition) method. The conductive layer 140 and the insulating film 141 are selectively removed in the memory area MA.

As shown in FIG. 10D, a conductive layer 143, an insulating film 144, an insulating film 145, an insulating film 146, and an insulating film 147 are sequentially stacked on the insulating film 137 in the memory area MA. The conductive layer 143 is, for example, a polysilicon layer. The insulating film 144 is, for example, a silicon nitride film. The insulating film 145 is, for example, a metal oxide film such as a hafnium oxide film. The insulating film 146 is, for example, an insulating film that contains silicon. The insulating film 147 is, for example, a silicon nitride film. The conductive layer 143, the insulating films 144, 145, 146 and 147 are formed by the use of CVD, for example. The conductive layer 143 and the respective insulating films are selectively removed in the peripheral area PA.

As shown in FIG. 10D, the upper surface of the insulating film 147 in the memory area and the upper surface of the insulating film 141 in the peripheral area PA are preferably provided at the same level. Matching the levels of the surface positions of the memory area MA and the peripheral area in this manner makes the processes for forming fine patterns easier.

As shown in FIG. 10E, trenches 151 and 153 are formed in the memory area MA, and a trench 155 is formed in the peripheral area PA. The trenches 151 and 153 are formed with a depth so as to reach in the semiconductor substrate 130 from the upper surface of the insulating film 147. The trench 151 is extended in the X-direction, and for example, multiple semiconductor bodies 10 are formed on the upper side of the semiconductor substrate 130. The trench 151 divides the insulating film 137, the conductive layer 143, and the insulating films 144, 145, 146, and 147. The trench 153 surrounds a portion where the memory cells MC are disposed, and is formed deeper than a depth of the trench 151. The trench 153 electrically insulates the memory cells MC from the other portions.

The trench 155 is formed with a depth so as to reach in the semiconductor substrate 130 from the upper surface of the insulating film 141. The trench 153 is extended in the X-direction, for example. Thus, multiple semiconductor bodies 10 are formed on the upper side of the semiconductor substrate 130 in the peripheral area PA.

A trench 155f provided between the memory area MA and the peripheral area PA includes a step portion 130q on the bottom surface thereof. The step portion 130q is formed at a position corresponding to the step portion 130p. Then, the trench 155f has a bottom surface 153a on the memory area MA side and a bottom surface 153b on the peripheral area PA side. The bottom surface 153b is provided at a level lower than a level of the bottom surface 153a.

Further, an STI 31 is formed inside the trench 151, and an STI 37 is formed inside the trenches 153 and 155. The STI 31 and the STI 37 are, for example, silicon oxide films. An STI 37f provided inside the trench 155f between the memory area MA and the peripheral area PA includes a step portion 130q at an end of a portion extending in the semiconductor substrate 130. Then, an end 37b on the peripheral area PA side of the STI 37f is provided at a level lower in the semiconductor substrate 130 than a level of an end 37a on the memory area MA side.

FIG. 10E is the cross-sectional view showing the semiconductor substrate 130 just after finishing a CMP (Chemical Mechanical Polishing) process, wherein a insulating film on the insulating films 141 and 147 is removed, leaving portions embedded in the trenches 153 and 155, to form the STI 31 and 37. The insulating films 141 and 147 act as polishing stoppers in the CMP process. Thereafter, the insulating films 141 and 147 are removed, and the manufacturing process shown in FIGS. 7A to 9B is applied to complete the non-volatile memory device 1.

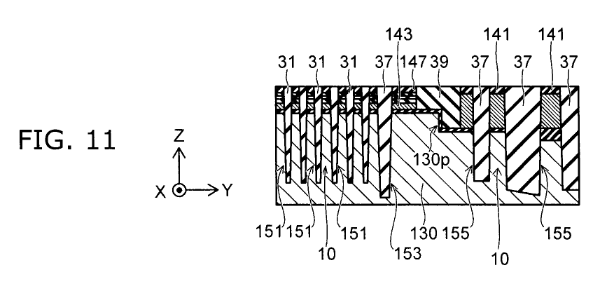

FIG. 11 is a schematic cross-sectional view illustrating a non-volatile memory device according to a variation of the second embodiment. The manufacturing process shown in FIGS. 10A to 10D is also used in the variation. FIG. 11 is also the cross-sectional view showing a semiconductor substrate 130 just after finishing a CMP process to form the STI 31 and 37. As shown in FIG. 11, in this example, the trench 155 is not formed in a portion where the step portion 130p is provided. Therefore, the step portion 130p remains on the top surface of the semiconductor substrate 130 between the memory area MA and the peripheral area PA.

Thereafter, the insulating films 141 and 147 are removed, and the manufacturing processes shown in FIGS. 7A to 9B are performed for completing the non-volatile memory device 1. In the manufacturing method according to the embodiment, the conductive layer 140 in the peripheral area PA is formed to be thicker than the conductive layer 143 in the memory area MA. Thus, the thickness of the conductive layer 73 in the resistor element 70 and the conductive layer 83 in the capacitor element 80 may be formed larger than the thickness of the charge storage layer 23.

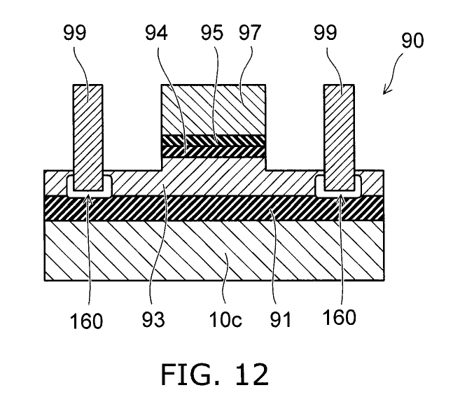

For example, FIG. 12 is a schematic cross-sectional view showing a resistor element 90 according to a comparative example. The resistor element 90 is formed on the third semiconductor body 10c via an insulating film 91. The resistor element 90 includes a conductive layer 93, insulating films 94 and 95, and a metal layer 97. The resistor element 90 has a contact member 99, which is in contact with the conductive layer 93 exposed by selectively removing the insulating films 94 and 95, and the metal layer 97.

The conductive layer 93 is, for example, a polysilicon layer, and the contact member 99 includes, for example, tungsten (W). Thus, it is preferable to provided tungsten silicide for decreasing the contact resistance between the conductive layer 93 and the contact member 99. In the case, however, where the film thickness of the conductive layer 93 is not sufficient to form the silicide, a void 160 may be generated between the conductive layer 93 and the contact member 99 after the silicidation of an end portion in the contact member 99. That is, the amount of silicon atoms is lacked around the end portion of the contact member 99 during the silicidation. Then, the void 160 may cause a contact failure in a peripheral circuit element.

For example, such a void 160 may be generated in the case where the conductive layer 93 is made from the conductive layer that has a thickness suitable for the charge storage layer in the memory cell MC. In the embodiment, the conductive layer 140 is formed to be thicker in the peripheral area PA than the charge storage layer in the memory cell MC. Thus, it becomes possible to form the silicide without the void 160, and thus, the reliability of the peripheral circuit element may be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A non-volatile memory device comprising:
a substrate including a first area and a second area around the first area;
first and second memory cells in the first area,
the first memory cell including:
a first semiconductor body extending in a first direction;
an electrode layer extending over the first semiconductor body in a second direction intersecting the first direction; and
a first stacked body provided at an intersection of the first semiconductor body and the electrode layer, the first stacked body including a first insulating film on the first semiconductor body, a first charge storage layer on the first insulating film and a second insulating film between the first charge storage layer and the electrode layer, and
the second memory cell sharing the electrode layer with the first memory cell, the second memory cell including:
a second semiconductor body extending in the first direction, the electrode layer extending over the second semiconductor body in the second direction; and
a second stacked body provided at an intersection of the second semiconductor body and the electrode layer, the second stacked body including a third insulating film on the second semiconductor body, a second charge storage layer on the third insulating film and a fourth insulating film between the second charge storage layer and the electrode layer;
a fifth insulating film provided between the first stacked body and the second stacked body; and
a sixth insulating film provided between the electrode layer and each of the second insulating film, the fourth insulating film and the fifth insulating film, the sixth insulating film being one of a single-layer film and a stacked film,
a first interface between the second insulating film and the sixth insulating film and a second interface between the fourth insulating film and the sixth insulating film being provided at the substantially same height level as a height level of a third interface between the fifth insulating film and the sixth insulating film; and
a capacitor element in the second area, the capacitor element including:
a third semiconductor body;
a first conductive layer provided on the third semiconductor body;
a dielectric film provided on the first conductive layer, the dielectric film including at least one layer that contains the same material as a material included in the sixth insulating film; and
a second conductive layer provided on the dielectric film.

2. The device according to claim 1, wherein the sixth insulating film contains a metal oxide film.

3. The device according to claim 1, wherein the sixth insulating film is a stacked film including a metal oxide film and an insulating film that contains silicon.

4. The device according to claim 2, wherein the metal oxide film is a hafnium oxide film.

5. The device according to claim 1, wherein each of the second insulating film and the fourth insulating film is a metal oxide film.

6. The device according to claim 1, wherein the first conductive layer is composed of a material that is the same as a material of the charge storage layer.

7. The device according to claim 6, wherein the charge storage layer is a polysilicon film.

8. The device according to claim 1, wherein the second conductive layer is composed of a material that is the same as a material of the electrode layer.

9. The device according to claim 1, wherein
the first insulating film is composed of a material that is the same as a material of the third insulating film; and
a seventh insulating film is formed between the third semiconductor body and the first conductive layer, the seventh insulating film being composed of a material that is the same as the material of the first insulating film and the third insulating film.

10. The device according to claim 1, wherein the capacitor element has a first contact member connected to the first conductive layer and a second contact member connected to the second conductive layer.

11. The device according to claim 1, further comprising:
a switching element in the second area, the switching element including:
a fourth semiconductor body;
an eighth insulating film provided on the fourth semiconductor body;
a third conductive layer provided on the eighth insulating film;
a fourth conductive layer provided on the third conductive layer; and
a source/drain region provided in the fourth semiconductor body on both sides of the eighth insulating film,
wherein the third conductive layer is composed of a material that is the same as a material of the charge storage layer, and
the fourth conductive layer is composed of a material that is the same as a material of the electrode layer.

12. The device according to claim 1, wherein the first conductive layer has a thickness larger than a thickness of the charge storage layer.

13. The device according to claim 12, wherein the semiconductor substrate has a first surface in the first area and a second surface in the second area, and the second surface provided at a lower level than a level of the first surface.

14. The device according to claim 1, wherein the semiconductor substrate has a first surface in the first area and a second surface in the second area, and the second surface provided at a lower level than a level of the first surface.

15. The device according to claim 1, wherein an insulating film is provided on a boundary between the first area and the second area, and the insulating film has a bottom surface at a lower level on the second area side than a level of a bottom surface thereof on the first area side.

16. A non-volatile memory device comprising:
a substrate having a first area and a second area around the first area;
first and second memory cells in the first area,
the first memory cell including:
a first semiconductor body extending in a first direction;
an electrode layer extending over the first semiconductor body in a second direction intersecting the first direction; and
a first stacked body provided at an intersection of the first semiconductor body and the electrode layer, the first stacked body including a first insulating film on the first semiconductor body, a first charge storage layer on the first insulating film, and a second insulating film between the first charge storage layer and the electrode layer, and
the second memory cell sharing the electrode layer with the first memory cell, the second memory cell including:
a second semiconductor body extending in the first direction, the electrode layer extending over the second semiconductor body in the second direction; and
a second stacked body provided at an intersection of the second semiconductor body and the electrode layer, the second stacked body including a third insulating film on the second semiconductor body, a second charge storage layer on the third insulating film, and a fourth insulating film between the second charge storage layer and the electrode layer;
a fifth insulating film provided between the first stacked body and the second stacked body;
a sixth insulating film provided between the electrode layer and each of the second insulating film, the fourth insulating film, and the fifth insulating film, the sixth insulating film is composed of a single-layer film or a stacked film,
a first interface between the second insulating film and the sixth insulating film and a second interface between the fourth insulating film and the sixth insulating film being provided at the substantially same height level as a third interface between the fifth insulating film and the sixth insulating film; and
a circuit element in the second area, the circuit element including:
a third semiconductor body; and
a conductive layer provided on the third semiconductor body via an insulating film, the conductive layer being composed of a material that is the same as a material of the charge storage layer, and
the conductive layer having a thickness larger than a thickness of the charge storage layer.

17. The device according to claim 16, wherein
the second area further includes an interlayer insulating film that covers the circuit element, a contact member that extends from an upper surface of the interlayer insulating film to the conductive layer and a metal silicide that is interposed between the conductive layer and the contact member.

18. The device according to claim 16, wherein an insulating film is provided on a boundary between the first area and the second area, and the insulating film has a bottom surface at a lower level on the second area side than a level of a bottom surface thereof on the first area side.

19. A non-volatile memory device comprising:
a semiconductor substrate having a first area and a second area adjacent to the first area, the second area having a first surface that is provided at a height level lower than a height level of a second surface in the first area;
a memory cell in the first area; and
an insulating film provided on a boundary between the first area and the second area.

20. The device according to claim 19, wherein the insulating film having a bottom surface at lower height level on the second area side than a height level of a bottom surface on the first area side.
